(19) United States
(12) Patent Application Publication
(10) Pub. No.: US 2025/0007128 A1
(43) Pub. Date: Jan. 2, 2025

(54) CONDUCTIVE MODULE AND POWER STORAGE DEVICE

(71) Applicants: YAZAKI CORPORATION, Tokyo (JP); TOYOTA JIDOSHA KABUSHIKI KAISHA, Toyota-shi (JP)

(72) Inventors: Yutaro OKAZAKI, Shizuoka (JP); Shinichi Yanagihara, Shizuoka (JP); Hiraku Tanaka, Shizuoka (JP); Kenta Tanaka, Shizuoka (JP); Satoshi Morioka, Aichi-ken (JP); Hiroyuki Kaiya, Aichi-ken (JP); Hiromi Ueda, Aichi-ken (JP); Shinpei Mune, Aichi-ken (JP); Naoto Morisaku, Aichi-ken (JP); Yutaro Kawabata, Aichi-ken (JP); Seigo Mochizuki, Shizuoka (JP)

(73) Assignees: YAZAKI CORPORATION, Tokyo (JP); TOYOTA JIDOSHA KABUSHIKI KAISHA, Toyota-shi (JP)

(21) Appl. No.: 18/736,082

(22) Filed: Jun. 6, 2024

(30) Foreign Application Priority Data
Jun. 28, 2023 (JP) 2023-106246

(51) Int. Cl. H01M 50/569; G01K 1/16; G01R 31/3835; H01M 50/503

(52) U.S. Cl. CPC H01M 50/569; G01K 1/16; G01R 31/3835; H01M 50/503

(57) ABSTRACT

A conductive module includes: a conductive board; a voltage detection terminal having a first location configured to be conductively connected to the conductive board; a temperature measurer including a temperature-measuring element and a case holding the temperature-measuring element; a plate-shaped housing assembled to the conductive board, the housing having a terminal accommodating recess accommodating the voltage detection terminal and a temperature measurer accommodating recess accommodating the temperature measurer; a heat-conductive filler disposed in a recessed groove of the temperature measurer accommodating recess; a cover configured to be locked to the housing at a temporary locking position where the first location of the voltage detection terminal accommodated in the terminal accommodating recess is not covered and a final locking position where the first location is covered; and an electric wire conductively connected to a second location of the voltage detection terminal and drawn out to the outside of the housing.

### CROSS-REFERENCE TO RELATED APPLICATION(S)

This application is based upon and claims the benefit of priority from prior Japanese patent application No. 2023-106246 filed on Jun. 28, 2023, the entire contents of which are incorporated herein by reference.

### BACKGROUND

### 1. Field of the Invention

The present disclosure relates to a conductive module including a conductive board as a detection target and a plate-shaped housing accommodating a voltage detection terminal and a temperature measurer, and a power storage device using the conductive module.

### 2. Description of the Related Art

The related art has proposed a stacked power storage device in which a plurality of chargeable and dischargeable thin power storage modules are connected in series via conductive boards by alternately arranging and repeatedly stacking the board-shaped power storage modules and the conductive boards. The power storage modules used in this type of power storage device generally have a structure in which a plurality of battery cells are incorporated, and function as one battery capable of charging and discharging. In one of the power storage devices of the related arts, in order to monitor the output state of each power storage module (that is, the potential of the output face of each power storage module relative to the zero potential as a reference; hereinafter, simply referred to as “voltage of the power storage module”), a detection terminal such as a bus bar is connected to the conductive board in contact with the output face of the power storage module, and the voltage of the power storage module is measured through the detection terminal (for example, see JP2020-161340A).

However, when actually connecting the bus bar or the like to the conductive board in the power storage device having the above-described structure, since the power storage modules and the conductive boards have a thin plate shape, it is difficult to secure a space for installing the other components for connection (for example, bolts for bolt fastening or the like). Therefore, the power storage device of the related art described above is provided with an insertion hole for inserting the detection terminal in the side edge of each conductive board. The detection terminal is inserted into the insertion hole of the conductive board from the lateral side of the stacked body in which the power storage modules and the conductive boards are stacked, thereby connecting the conductive board and the detection terminal. However, according to this connection method of the related art, the positioning between the insertion hole of the conductive board and the detection terminal is complicated when inserting the detection terminal, which makes it difficult to improve the workability of connection work.

### SUMMARY

An object of the present disclosure is to provide a conductive module excellent in workability in a conductive connection with a detection target, and a power storage device using the conductive module.

In order to achieve the object described above, a conductive module and a power storage device according to the present disclosure are characterized as follows.

According to an aspect of the present disclosure, there is provided a conductive module including: a conductive board; a voltage detection terminal having a first location configured to be conductively connected to the conductive board; a temperature measurer including a temperature-measuring element and a case holding the temperature-measuring element; a plate-shaped housing assembled to the conductive board, the housing having a terminal accommodating recess accommodating the voltage detection terminal and a temperature measurer accommodating recess accommodating the temperature measurer; a heat-conductive filler disposed in a recessed groove of the temperature measurer accommodating recess; a cover configured to be locked to the housing at a temporary locking position where the first location of the voltage detection terminal accommodated in the terminal accommodating recess is not covered and a final locking position where the first location is covered; and an electric wire conductively connected to a second location of the voltage detection terminal and drawn out to the outside of the housing, in which: the housing is configured such that a part of the conductive board is exposed in the recessed groove of the temperature measurer accommodating recess; and the filler is in contact with both the temperature-measuring element and the part of the conductive board.

According to another aspect of the present disclosure, there is provided a power storage device including: the conductive module; and a power storage module configured to be charged and discharged, on which the conductive module is stacked.

According to the conductive module and the power storage device according to the present disclosure, the cover can be locked to the housing while accommodating the voltage detection terminal whose second location is connected to the electric wire in the terminal accommodating recess of the housing and exposing the first location of the voltage detection terminal. Therefore, when the voltage detection unit is electrically connected to a detection target (for example, a conductive board or the like used in a stacked power storage device), for example, after the voltage detection unit is assembled to the detection target, the exposed first location of the voltage detection terminal can be fixed to the detection target using a method such as ultrasonic joining or welding. This does not require another component for connection as compared to typical bolt fastening or the like, and can easily align the two components and reduce the contact resistance at the contact point as compared to the connection methods of the related art described above. By disposing the cover at the final locking position after the detection target and the voltage detection terminal are connected, the first location of the voltage detection terminal (that is, the contact point therebetween) can be covered and protected by the cover.

Further, the temperature measurer is accommodated in the temperature measurer accommodating recess of the housing, so that both the temperature-measuring element of the temperature measurer and a part of the conductive board exposed in the recessed groove of the temperature measurer accommodating recess are arranged in the recessed groove. Simultaneously, a heat-conductive filler (for example, a sealing material that is flexible at the time of filling and is hardened with time) is disposed in the recessed groove to be in contact with both the temperature-measuring element and a part of the conductive board. Accordingly, an air layer that hinders the heat conduction therebetween is less likely to exist as compared to a case in which the temperature-measuring element and the conductive board are simply disposed adjacent to each other. Accordingly, the temperature measurer can accurately measure the temperature of the conductive board (in other words, for example, the temperature of the power storage module conducted through the conductive board in a stacked power storage device).

Therefore, the conductive module and the power storage device according to the present disclosure are excellent in workability for conductively connecting to the detection target. Further, the conductive module and the power storage device according to the present disclosure can improve the accuracy of the temperature measurement by the temperature measurer.

The present disclosure has been briefly described above. Further, details of the present disclosure can be clarified by reading modes (hereinafter, referred to as “embodiments”) for carrying out the disclosure to be described below with reference to the accompanying drawings.

### BRIEF DESCRIPTION OF THE DRAWINGS

The present disclosure will become more fully understood from the detailed description given hereinbelow and the accompanying drawing which is given by way of illustration only, and thus is not limitative of the present disclosure and wherein:

FIG. 1 is a partially exploded perspective view illustrating a stacked power storage device including a conductive module according to an embodiment of the present disclosure;

FIG. 2 is a cross-sectional view taken along a line A-A of FIG. 1;

FIG. 3 is an enlarged view of a portion B in FIG. 2;

FIG. 4 is an exploded perspective view of a voltage detection unit constituting the conductive module illustrated in FIG. 1;

FIG. 5 is a top view illustrating a state in which a cover is locked to a first housing at a final locking position;

FIG. 6 is a cross-sectional view taken along a line C-C in FIG. 5;

FIG. 7 is a perspective view illustrating a conductive board, a second housing, and a thermistor constituting the conductive module illustrated in FIG. 1;

FIG. 8 is a perspective view of the thermistor illustrated in FIG. 7;

FIG. 9 is a front view of the thermistor illustrated in FIG. 7;

FIG. 10 is a top view illustrating a state in which the thermistor is accommodated in the second housing;

FIG. 11 is a perspective view illustrating a state in which a sealing material is applied to the upper face of the second housing and filled in a recessed groove of a thermistor accommodating recess illustrated in FIG. 10;

FIG. 12 is a top view illustrating a state in which the sealing material is applied to the upper face of the second housing and filled in the recessed groove of the thermistor accommodating recess illustrated in FIG. 10;

FIG. 13 is a cross-sectional view taken along a line D-D in FIG. 12; and

FIG. 14 is a cross-sectional view taken along a line A-A in FIG. 12.

### DETAILED DESCRIPTION OF THE INVENTION

### Embodiment

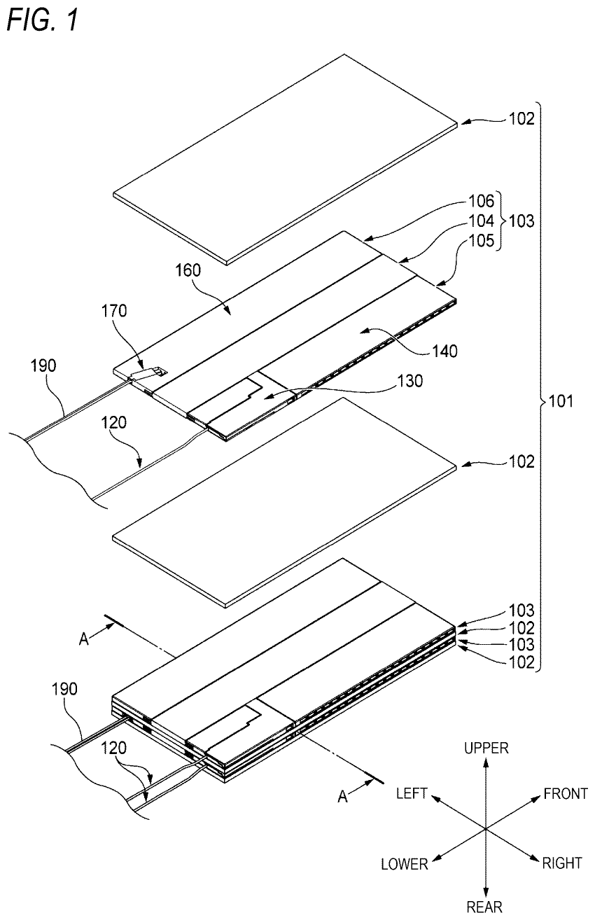

Hereinafter, a conductive module 103 according to an embodiment of the present disclosure and a power storage device 101 using the conductive module 103 will be described with reference to the drawings. Hereinafter, for convenience of description, “front”, “rear”, “upper”, “lower”, “left”, “right”, a “front-rear direction”, a “left-right direction”, and an “upper-lower direction” are defined as illustrated in FIG. 1. The “front-rear direction”, the “left-right direction”, and the “upper-lower direction” are orthogonal to one another.

As illustrated in FIG. 1, the power storage device 101 is formed by alternately stacking, in the upper-lower direction, rectangular thin board-shaped power storage modules 102 capable of charging and discharging and rectangular thin board-shaped conductive modules 103 capable of electrically connecting adjacent power storage modules 102. In the power storage device 101, a plurality of power storage modules 102 are electrically connected in series via the conductive modules 103. Each power storage module 102 has a structure in which a plurality of battery cells (not illustrated) are incorporated, and the power storage modules 102 as a whole function as one battery capable of charging and discharging.

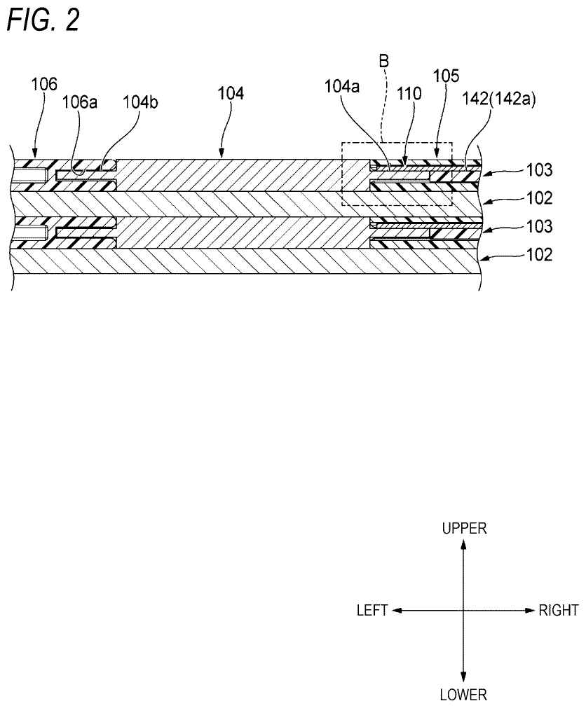

As illustrated in FIG. 1, each conductive module 103 is formed to have a rectangular thin board shape as a whole by a rectangular thin board-shaped conductive board 104 (the conductive board 104 also functions as a heat sink as described later), the rectangular thin board-shaped voltage detection unit 105 coupled to the right side of the conductive board 104, and a rectangular thin board-shaped temperature detection unit 106 coupled to the left side of the conductive board 104. As illustrated in FIGS. 1 to 3 (in particular, see FIG. 2), the conductive board 104 and the voltage detection unit 105 are coupled to each other by fitting a flange 104a into a recess 105a. The flange 104a is provided on the right end face of the conductive board 104 and extends in the front-rear direction. The recess 105a is provided on the left end face of the voltage detection unit 105 and extends in the front-rear direction. The conductive board 104 and the temperature detection unit 106 are coupled to each other by fitting a flange 104b into a recess 106a. The flange 104b is provided on the left end face of the conductive board 104 and extends in the front-rear direction. The recess 106a is provided on the right end face of the temperature detection unit 106 and extends in the front-rear direction.

In each of the conductive modules 103 positioned between the power storage modules 102 adjacent to each other in the upper-lower direction, the conductive board 104 is in direct contact with the upper and lower power storage modules 102 as illustrated in FIG. 2. Thus, the conductive board 104 functions to perform conduction between the lower face of the upper power storage module 102 and the upper face of the lower power storage module 102, and functions as a heat sink that releases heat generated from the upper and lower power storage modules 102 to the outside.

In each of the conductive modules 103 located between the power storage modules 102 adjacent to each other in the upper-lower direction, the voltage detection unit 105 includes a voltage detection terminal 110 (see FIG. 2, etc.) in contact with the conductive board 104, which is to be described later. The voltage detection unit 105 has a function of outputting a signal indicating a voltage between the upper and lower power storage modules 102 (specifically, the potential of the upper face (output face) of the lower power storage module 102 relative to the zero potential as a reference) via an electric wire 120 (see FIG. 1, etc.) connected to the voltage detection terminal 110.

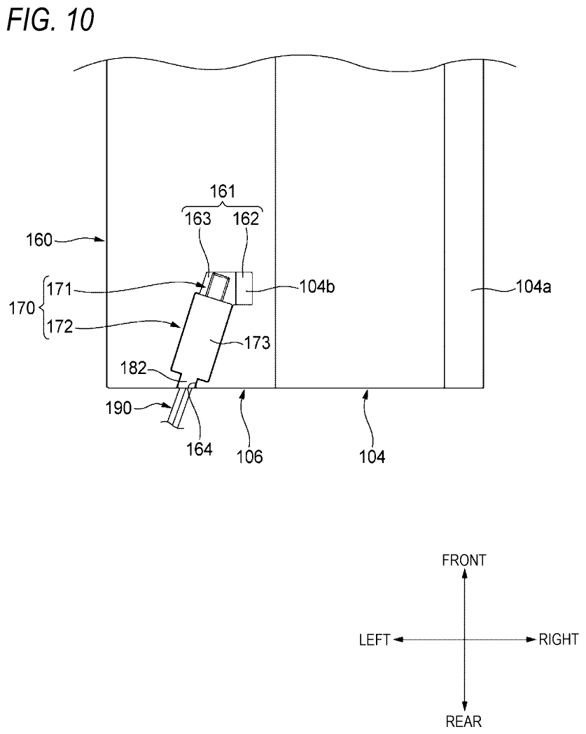

In each of the conductive modules 103 located between the power storage modules 102 adjacent to each other in the upper-lower direction, the temperature detection unit 106 includes a thermistor 170 (see FIGS. 1, 10, etc.) arranged adjacent to a part of the conductive board 104 (more specifically, the flange 104b), which is to be described later. The temperature detection unit 106 functions to output a signal indicating the temperature of the conductive board 104 (and hence the power storage modules 102 in contact with the upper and lower faces of the conductive board 104) via an electric wire 190 (see FIG. 1 and the like) connected to the thermistor 170.

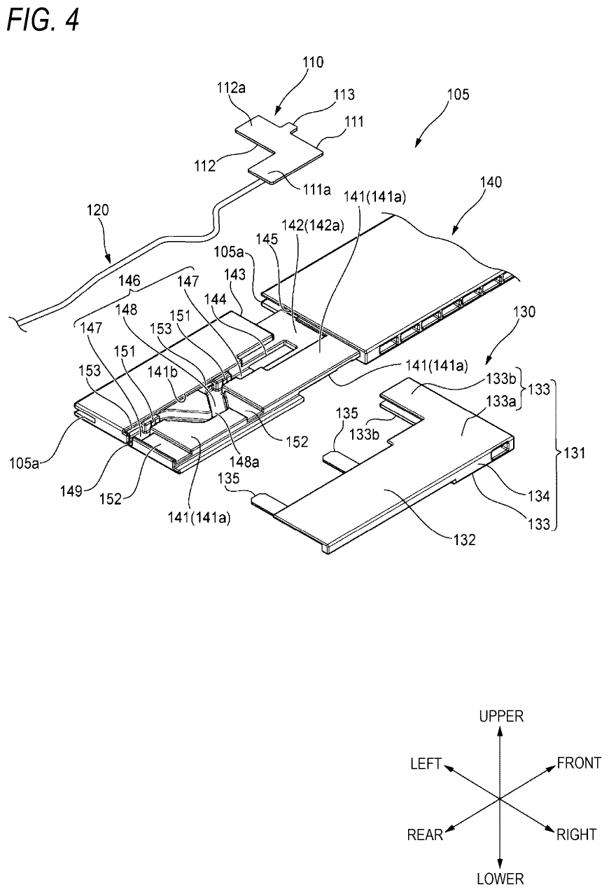

Next, a specific configuration of the voltage detection unit 105 will be described with reference to FIGS. 4 to 6. As illustrated in FIG. 4, the voltage detection unit 105 includes a first housing 140, a voltage detection terminal 110 accommodated in the first housing 140, the electric wire 120 connected to the voltage detection terminal 110 and accommodated in the first housing 140, and a cover 130 mounted to the first housing 140.

The voltage detection terminal 110 is accommodated in a terminal accommodating recess 142 (see FIG. 4) formed in the first housing 140, which will be described later. The electric wire 120 is accommodated in an electric wire accommodating recess 146 (see FIG. 4) formed in the first housing 140, which is to be described later. The cover 130 is mounted in cover mounting recesses 141 (see FIG. 4) formed in the first housing 140, which is to be described later. Hereinafter, the members constituting the voltage detection unit 105 will be described in order.

First, the voltage detection terminal 110 will be described. The voltage detection terminal 110 made of metal is formed by processing one metal board via pressing or the like. The voltage detection terminal 110 is accommodated in the terminal accommodating recess 142 of the first housing 140 from above. As illustrated in FIG. 4, the voltage detection terminal 110 includes a rectangular flat plate-shaped first portion 111 extending in the front-rear direction and a rectangular flat plate-shaped second portion 112 extending leftward from the front end of the first portion 111, and has a substantially L-shaped flat plate shape as a whole when viewed in the upper-lower direction.

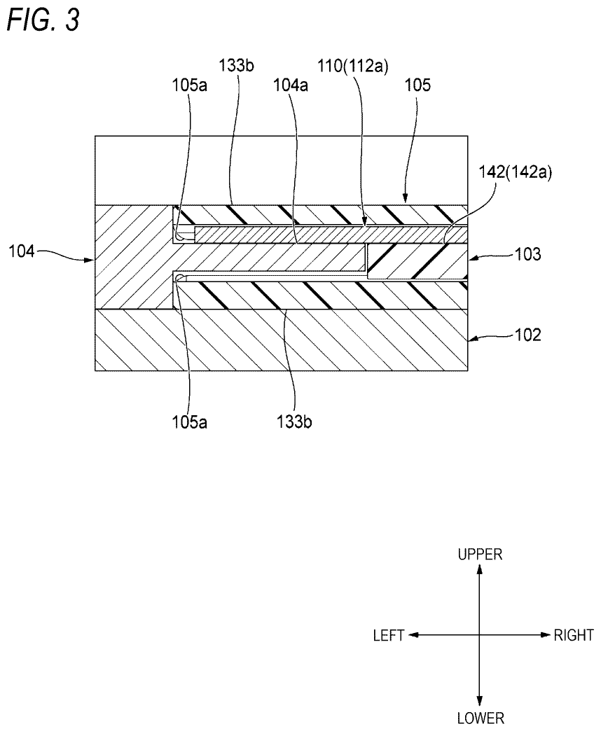

One end of the electric wire 120 is fixed and electrically connected to the lower face of the tip portion 111a of the first portion 111 (that is, the end closer to the rear end). The other end of the electric wire 120 is to be connected to a voltage measuring device (not illustrated) outside the power storage device 101. Apart of the flange 104a of the conductive board 104 is to be fixed to the lower face of a tip portion 112a of the second portion 112 (that is, the end closer to the left end) by a method such as ultrasonic joining or welding (see FIG. 3).

The front end edge of the second portion 112 is formed with a projection 113 projecting forward. When the voltage detection terminal 110 is accommodated in the first housing 140, the projection 113 is to be locked in a locking groove 145 (see FIG. 4) formed in the first housing 140.

Next, the cover 130 will be described. The cover 130 is a resin molded article and is mounted to the cover mounting recesses 141 of the first housing 140 from the right. The cover 130 includes a facing portion 131 and an extension portion 132 extending rearward from the facing portion 131. The facing portion 131 mainly functions to cover and protect the voltage detection terminal 110, and the extension portion 132 mainly functions to cover and protect the electric wire 120.

The facing portion 131 includes a pair of flat plates 133 having the same shape and facing each other at an interval in the upper-lower direction, and a coupling portion 134 that couples the right end edges of the pair of flat plates 133 extending in the front-rear direction in the upper-lower direction over the entire region in the front-rear direction. The facing portion 131 has a substantially U-shape opening leftward when viewed in the front-rear direction. Each flat plate 133 includes a substantially square flat plate-shaped a base 133a continuous from the coupling portion 134, and a rectangular flat plate-shaped extension portion 133b extending leftward from the front end of the base 133a, and has a substantially L shape as a whole when viewed in the upper-lower direction. The extension portion 132 extends rearward from the rear end edge of the upper flat plate 133 (more specifically, the upper base 133a) of the pair of flat plates 133 constituting the facing portion 131 in a flush and continuous manner, and has a substantially rectangular flat plate shape.

The extension portion 132 is integrally formed with two electric wire holding pieces 135 extending in the left-right direction, which are arranged at an interval in the front-rear direction. Each electric wire holding piece 135 protrudes downward from the lower face of the extension portion 132 and extends in the left-right direction, so as to project further leftward from the left end edge of the extension portion 132. When the cover 130 is mounted to the first housing 140, the electric wire holding pieces 135 hold the electric wire 120 accommodated in the first housing 140.

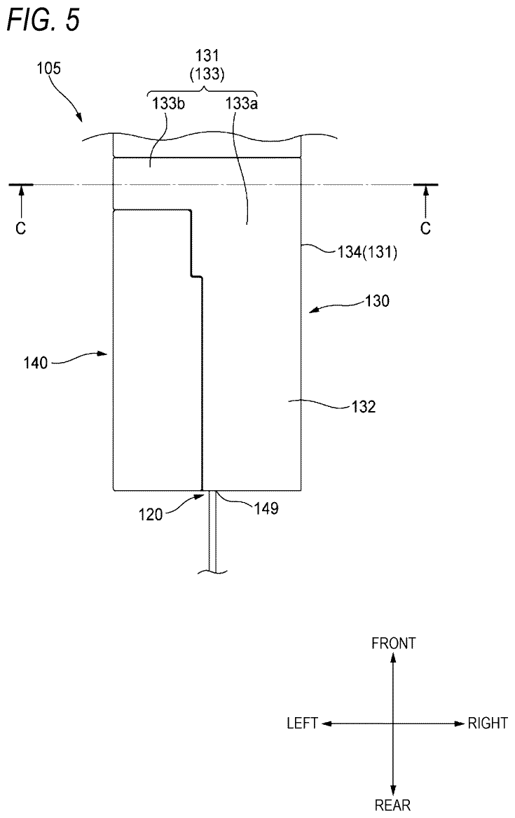

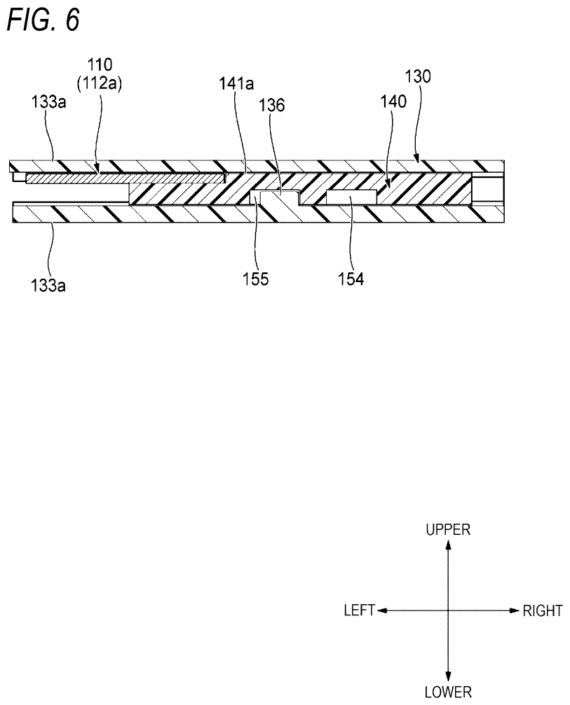

The lower flat plate 133 (more specifically, the lower base 133a) of the pair of flat plates 133 constituting the facing portion 131 is formed with a locking portion 136 projecting upward toward the upper flat plate 133 at a predetermined location (see FIG. 6). The locking portion 136 functions to lock the cover 130 to a temporary locking position (not illustrated) and a final locking position (see FIGS. 5 and 6) in cooperation with a temporary locked portion 154 and a final locked portion 155 (see FIG. 6) provided in the first housing 140, which is to be described later.

Next, the first housing 140 will be described. The first housing 140 is a resin molded article and has a substantially rectangular thin board shape extending in the front-rear direction as illustrated in FIGS. 1 and 4. The left end face of the first housing 140 is formed with a recess 105a recessed rightward and extending in the front-rear direction. The flange 104a of the conductive board 104 is to be fitted into the recess 105a (see FIG. 2, etc.).

The locations on the upper and lower faces of the first housing 140 where the cover 130 is mounted are each formed with the cover mounting recess 141 recessed into a shape corresponding to the entire shape of the cover 130 (see FIG. 4). The recess depth (depth in the upper-lower direction) of the cover mounting recesses 141 is equal to the plate thickness of the resin material constituting the cover 130 (the facing portion 131+the extension portion 132). Thus, when the cover 130 is mounted to the first housing 140, the face of the first housing 140 is flush with the face of the cover 130 (see FIGS. 1 and 5).

The location where the voltage detection terminal 110 is accommodated on a bottom face 141a of the cover mounting recess 141 in the upper face of the first housing 140 is formed with a terminal accommodating recess 142 further recessed into a shape corresponding to the entire shape of the voltage detection terminal 110 (see FIG. 4). The recess depth (depth in the upper-lower direction) of the terminal accommodating recess 142 is equal to the plate thickness of the voltage detection terminal 110. Thus, when the voltage detection terminal 110 is mounted to the first housing 140, the upper face of the voltage detection terminal 110 is flush with the bottom face 141a of the cover mounting recess 141.

The position in the front-rear direction in the left end edge of the first housing 140 where the tip portion 112a of the voltage detection terminal 110 is disposed is formed with a notch 143 recessed rightward into a substantially rectangular shape when viewed in the upper-lower direction. The recess 105a extending in the front-rear direction in the left end face of the first housing 140 is divided by the notch 143. When the voltage detection terminal 110 is accommodated in the first housing 140, the upper and lower faces of the tip portion 112a of the voltage detection terminal 110 are to be exposed by the notch 143.

The location in the terminal accommodating recess 142 where the tip portion 111a of the voltage detection terminal 110 is disposed is formed with a through hole 144 extending in the front-rear direction and penetrating in the upper-lower direction. When the voltage detection terminal 110 is accommodated in the first housing 140, the one end (contact point) of the electric wire 120 connected to the voltage detection terminal 110 enters the through hole 144. In other words, the through hole 144 functions as a clearance for avoiding interference between the bottom face 142a of the terminal accommodating recess 142 and the one end of the electric wire 120.

The inner wall face of the location in the terminal accommodating recess 142 where the projection 113 (see FIG. 4) of the voltage detection terminal 110 is disposed is formed with a locking groove 145 recessed forward and communicating with the recess 105a, so as to correspond to the projection 113 (see FIG. 4).

The location on the upper face of the first housing 140 where the electric wire 120 is accommodated is formed with an electric wire accommodating recess 146 having a shape corresponding to the wiring form of the electric wire 120 when the electric wire 120 is accommodated (see FIG. 4). The electric wire accommodating recess 146 is a continuous groove including a pair of straight portions 147 extending linearly in the front-rear direction and arranged at an interval in the front-rear direction, and a bent portion 148 connecting the pair of straight portions 147 and extending while being bent to project rightward. The front end of the front straight portion 147 of the pair of straight portions 147 communicates with the terminal accommodating recess 142, and the rear end of the rear straight portion 147 of the pair of straight portions 147 constitutes an electric wire outlet 149 from which the electric wire 120 extends from the rear end edge of the first housing 140. In this way, since the electric wire accommodating recess 146 has the bent portion 148, as compared with a case where the electric wire accommodating recess 146 is formed of only the straight portions 147, even if an unintended external force is applied to the electric wire 120 drawn out from the first housing 140, the electric wire 120 can resist the external force due to the friction between the bent portion 148 and the electric wire 120. Thus, a large external force is hardly applied to the contact point between the voltage detection terminal 110 and the electric wire 120.

The location in each of the pair of straight portions 147 near the boundary with the bent portion 148 is provided with a narrow recess 151, which is a recess having a width (interval in the left-right direction) narrower than that of the straight portion 147. The width of the narrow recess 151 is slightly smaller than the outer diameter of the electric wire 120. Thus, the electric wire 120 is pinched while being pressed in the left-right direction. By pinching the electric wire 120 between the pair of narrow recesses 151, even if an unintended external force is applied to the electric wire 120 drawn out from the first housing 140, it is possible to resist the external force by friction between the narrow recesses 151 and the electric wire 120. Thus, a large external force is hardly applied to the contact point between the voltage detection terminal 110 and the electric wire 120. Further, it is possible to strongly prevent the electric wire 120 from being wired in a manner coming out of the bent portion 148 and straddling the bent portion 148 (that is, shortcutting the bent portion 148).

As illustrated in FIG. 4, the locations on the bottom face 141a of the cover mounting recess 141 in the upper face of the first housing 140 at which the pair of electric wire holding pieces 135 of the cover 130 are arranged are formed with a pair of electric wire holding piece recesses 152 extending in the left-right direction at an interval in the front-rear direction, so as to correspond to the pair of electric wire holding pieces 135. The pair of electric wire holding piece recesses 152 sandwich a bending vertex 148a (see FIG. 4) of the bent portion 148 of the electric wire accommodating recess 146 in the front-rear direction. The bottom faces of the pair of electric wire holding piece recesses 152 are located above the bottom face of the electric wire accommodating recess 146.

The electric wire holding piece recesses 152 extend in the left-right direction from the right end edge of the upper face of the first housing 140 to the left inner wall 141b (see FIG. 4) of the cover mounting recess 141 across the electric wire accommodating recess 146. Each of the locations on the left inner wall 141b of the cover mounting recess 141 where the pair of electric wire holding piece recesses 152 are connected is formed with a storage hole 153 recessed leftward (see FIG. 4). When the cover 130 is mounted to the first housing 140, the extension ends (that is, the left end) of the pair of electric wire holding pieces 135 of the cover 130 are to be inserted and stored in the pair of storage holes 153.

As illustrated in FIG. 6, the same position in the front-rear direction as the location where the locking portion 136 of the cover 130 is disposed on the bottom face 141a of the cover mounting recess 141 in the lower face of the first housing 140 is formed with the temporary locked portion 154 and the final locked portion 155, which are recesses recessed upward, in this order at an interval from the right to the left. The members constituting the voltage detection unit 105 have been described above.

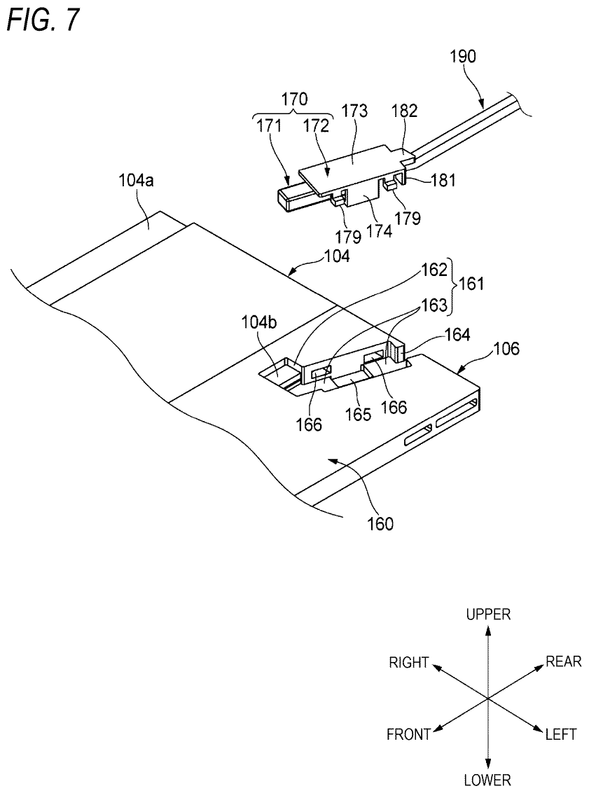

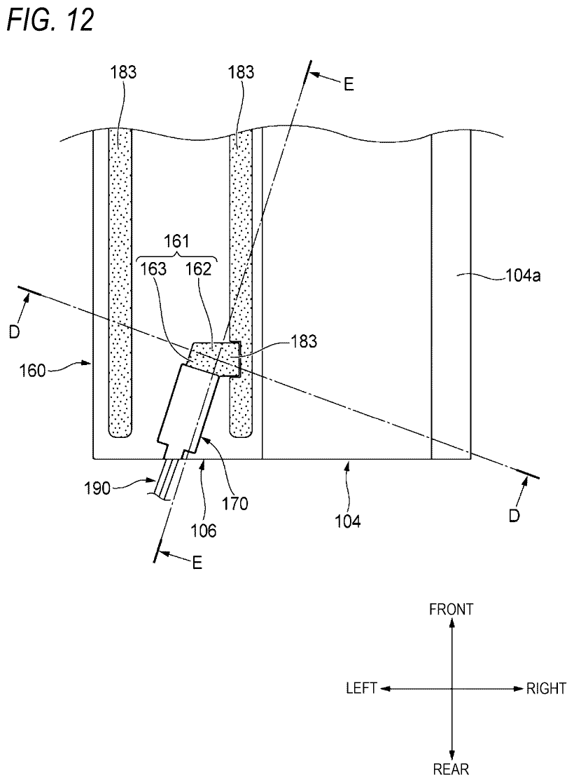

Next, a specific configuration of the temperature detection unit 106 will be described with reference to FIGS. 7 to 14. As illustrated in FIG. 7, the temperature detection unit 106 includes a second housing 160, a thermistor 170 accommodated in the second housing 160, and an electric wire 190 connected to the thermistor 170. The thermistor 170 is accommodated in a thermistor accommodating recess 161 formed in the second housing 160 (see FIG. 7, etc.), which is to be described later. Hereinafter, the members constituting the temperature detection unit 106 will be described in order. The thermistor 170 corresponds to a “temperature measurer” in the present disclosure, and a thermistor element 171 corresponds to a “temperature-measuring element” in the present disclosure.

First, the second housing 160 will be described. The second housing 160 is a resin molded article and has a substantially rectangular thin board shape extending in the front-rear direction as illustrated in FIG. 1, 7, etc. The right end face of the second housing 160 is formed with a recess 106a recessed leftward and extending in the front-rear direction (see FIGS. 2, 13 and 14). The flange 104b of the conductive board 104 is to be fitted into the recess 106a (see FIGS. 2, 13 and 14).

The upper face in the vicinity of the rear end of the second housing 160 extending in the front-rear direction is formed with a thermistor accommodating recess 161 having a shape corresponding to the overall shape of the thermistor 170 (see FIG. 7). The recess depth (depth in the upper-lower direction) of the thermistor accommodating recess 161 corresponds to the thickness (length in the upper-lower direction) of the thermistor 170. Thus, when the thermistor 170 is mounted to the second housing 160, the face of the second housing 160 is flush with the face of the thermistor 170 (see FIGS. 1, 10, etc.).

As illustrated in FIG. 7, etc., the thermistor accommodating recess 161 includes a first recess 162 extending in the left-right direction and a second recess 163 extending rearward and leftward (hereinafter referred to as “longitudinal direction”) from the left end of the first recess 162. The right end of the first recess 162 communicates with a part in the front-rear direction of the recess 106a extending in the front-rear direction of the second housing 160. Therefore, by fitting the flange 104b of the conductive board 104 in the recess 106a, a part of the flange 104b of the conductive board 104 in the front-rear direction (hereinafter, also simply referred to as “part 104b of the conductive board 104”) is exposed in the recessed groove at the right end of the first recess 162 (see FIGS. 7 and 10).

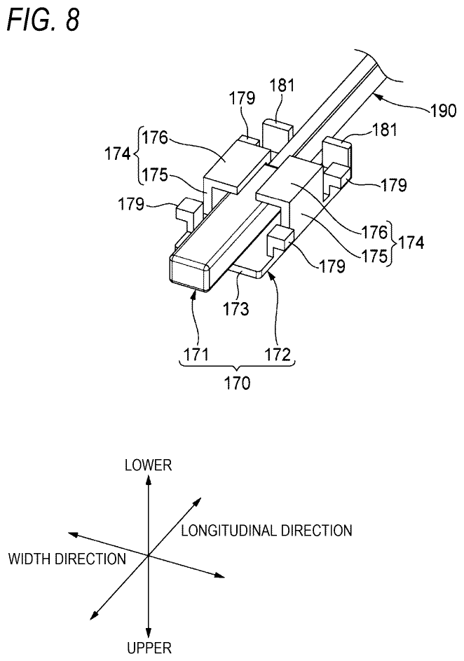

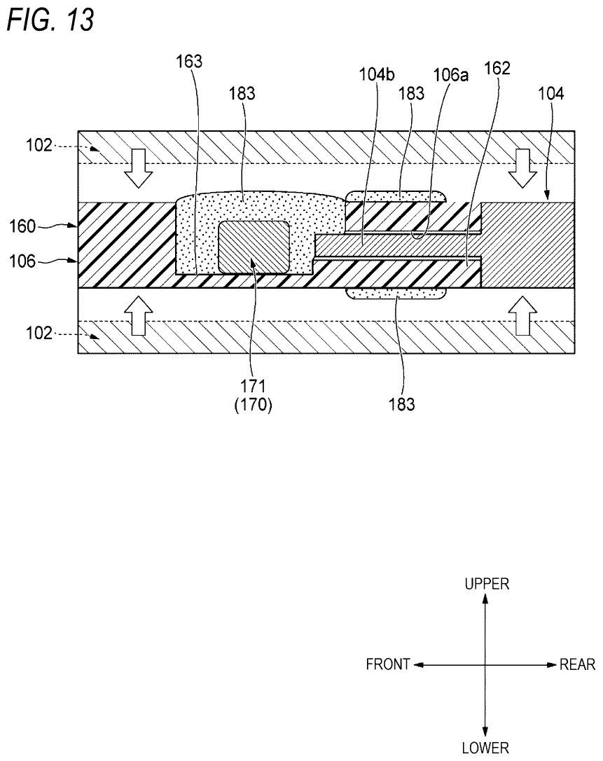

As illustrated in FIG. 7 and the like, the end on one side in the longitudinal direction of the second recess 163 extending in the longitudinal direction communicates with the left end of the first recess 162, and the end on the other side of the second recess 163 in the longitudinal direction communicates with the outside of the second housing 160 via the communication recess 164. The recess depth (depth in the upper-lower direction) of the first recess 162 is smaller than the recess depth (depth in the upper-lower direction) of the second recess 163 (see FIG. 13). The bottom face of the first recess 162 is continuous with the lower inner wall face of the recess 106a without any step (see FIG. 13). The central portion in the longitudinal direction on the bottom face of the second recess 163 is formed with a through hole 165 penetrating in the upper-lower direction and having a shape corresponding to the shape a pair of holding portions 174 (more specifically, a pair of lateral walls 176; see FIG. 8, etc.) provided in a case 172 of the thermistor 170, which will be described later (see FIG. 7). Four positions adjacent to the front and rear sides of the through hole 165 in the inner faces of both sides of the second recess 163 are formed with locking holes 166 recessed outward in the width direction (direction orthogonal to the longitudinal direction) of the second recesses 163, corresponding to four locking projections 179 (see FIG. 7, etc.) provided on the case 172 of the thermistor 170.

Next, the thermistor 170 will be described. As illustrated in FIG. 10, the thermistor 170 is to be accommodated in the second recess 163 of the thermistor accommodating recess 161. Therefore, the thermistor 170 has a shape whose longitudinal direction corresponds to the longitudinal direction of the second recess 163, and includes the thermistor element 171 constituting the temperature-measuring element and the case 172 holding the thermistor element 171 (see FIGS. 7, 8, etc.). In this example, the thermistor element 171 has a substantially rectangular parallelepiped shape extending in the longitudinal direction (see FIG. 8, etc.). The electric wire 190 extends from the other end of the thermistor element 171 in the longitudinal direction.

The case 172 is made of resin and includes, as illustrated in FIG. 8, etc., a rectangular flat plate-shaped top plate 173 extending in the longitudinal direction, and a pair of holding portions 174 extending downward from the central portion in the longitudinal direction of both the edges in the width direction of the top plate 173. The top plate 173 functions to close the opening of the second recess 163 of the thermistor accommodating recess 161 when the thermistor 170 is accommodated in the second recess 163 (see FIG. 10, etc.). The pair of holding portions 174 function to hold the thermistor element 171.

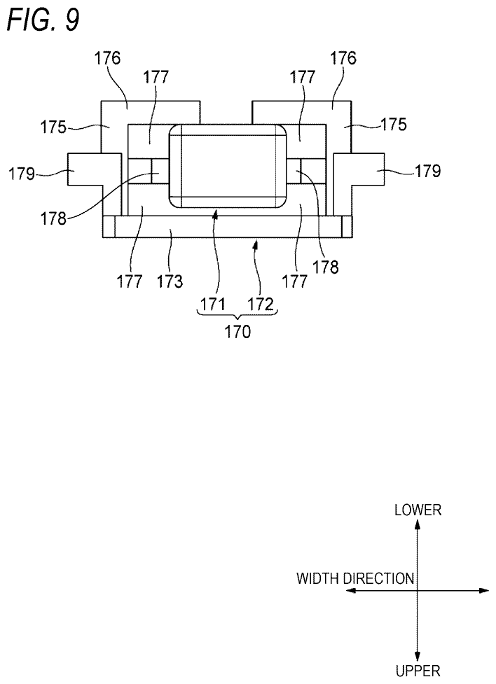

More specifically, as illustrated in FIGS. 8 and 9, the pair of holding portions 174 include a pair of flat plate-shaped vertical walls 175 extending downward from both the edges in the width direction of the top plate 173, and a pair of flat plate-shaped lateral walls 176 extending inward in the width direction from the extension ends (lower ends) of the pair of vertical walls 175. A gap in the width direction is present between the extension ends (inner ends in the width direction) of the pair of lateral walls 176. The pair of holding portions 174 are provided with a pair of flat plate-shaped back walls 177 extending in the upper-lower direction and the width direction so as to couple the rear end edges of the pair of lateral walls 176 and the top plate 173 in the upper-lower direction and to be coupled to the rear end edges of the pair of vertical walls 175 (see FIG. 9). A gap in the width direction is also present between the inner ends in the width direction of the pair of back walls 177. Further, the pair of holding portions 174 are provided with a pair of locking projections 178 for locking the thermistor element 171 in a manner extending inward in the width direction from the inner side faces in the width direction of the pair of vertical walls 175 (see FIG. 9).

Four positions adjacent to the front and rear sides of the pair of holding portions 174 disposed at both the side edges in the width direction of the top plate 173 are formed with four locking projections 179 projecting downward. Both the ends in the width direction of the rear end edge of the top plate 173 are formed with a pair of flat plate-shaped rear walls 181 projecting downward. Further, the central portion in the width direction of the rear end edge of the top plate 173 is formed with a flat plate-shaped extended plate 182 further extending rearward. The extended plate 182 functions to close the opening of the communication recess 164 when the thermistor 170 is accommodated in the second recess 163 of the thermistor accommodating recess 161 (see FIG. 10, etc.).

To assemble the thermistor element 171 to the case 172 (to hold the thermistor element 171 in the pair of holding portions 174 of the case 172), first, in a state where the entire thermistor element 171 is arranged on one side in the longitudinal direction relative to the pair of holding portions 174, the electric wire 190 extending rearward from the thermistor element 171 is inserted into the gap between the pair of lateral walls 176 and the pair of back walls 177 and the gap between the pair of rear walls 181. Next, the thermistor element 171 is inserted into a space defined by the pair of holding portions 174 (=vertical walls 175+lateral walls 176) from the one side to the other side in the longitudinal direction. In this insertion process, the thermistor element 171 moves relatively to the other side in the longitudinal direction in the space while the pair of locking projections 178 slide on the outer faces on both sides of the thermistor element 171. When the end on the other side of the thermistor element 171 in the longitudinal direction comes into contact with the pair of back walls 177, the thermistor element 171 is completely assembled to the case 172, and the thermistor element 171 is locked and held while being pinched between the pair of locking projections 178 in the width direction (see FIGS. 8 and 9). In the state where the thermistor element 171 is completely assembled to the case 172, as illustrated in FIGS. 7, 8, etc., the end on the one side in the longitudinal direction of the thermistor element 171 projects toward the one side in the longitudinal direction from the end on the one side in the longitudinal direction of the case 172 (more specifically, the top plate 173), and is exposed to the outside. The members constituting the temperature detection unit 106 have been described above.

Next, a procedure for assembling the conductive module 103 will be described. First, a procedure for assembling the voltage detection unit 105 to the conductive board 104 will be described. To assemble the voltage detection unit 105 to the conductive board 104, first, the voltage detection terminal 110 and the cover 130 are assembled to the first housing 140 to complete the voltage detection unit 105. Thereafter, the completed voltage detection unit 105 is coupled to the conductive board 104.

To assemble the voltage detection terminal 110 and the cover 130 to the first housing 140, first, the voltage detection terminal 110 which is connected to the electric wire 120 in advance by a method such as ultrasonic joining or welding is accommodated in the terminal accommodating recess 142 of the first housing 140. Thus, the voltage detection terminal 110 is fitted into the terminal accommodating recess 142 of the first housing 140 from above such that the projection 113 enters the locking groove 145 and the one end (contact point) of the electric wire 120 enters the through hole 144. In a state in which the voltage detection terminal 110 is completely accommodated in the first housing 140, the upper and lower faces of the tip portion 112a of the voltage detection terminal 110 are exposed by the notch 143.

Next, the electric wire 120 extending from the voltage detection terminal 110 accommodated in the first housing 140 is accommodated in the electric wire accommodating recess 146 of the first housing 140. Thus, the electric wire 120 is fitted from above along the electric wire accommodating recess 146 constituted by the pair of straight portions 147 and the bent portion 148. At this time, a pair of portions of the electric wire 120 positioned at the upper portions of the pair of narrow recesses 151 are pushed downward, so that the pair of portions of the electric wire 120 are accommodated in the pair of narrow recesses 151. In a state in which the electric wire 120 is completely accommodated in the first housing 140, the electric wire 120 extends rearward from the electric wire outlet 149 to the outside of the first housing 140.

Next, the cover 130 is mounted to the first housing 140. Thus, the cover 130 is mounted in the cover mounting recesses 141 of the first housing 140 from the right side, such that the facing portion 131 of the cover 130 sandwiches the cover mounting recesses 141 in the upper and lower faces of the first housing 140 in the upper-lower direction, the extension portion 132 of the cover 130 covers the cover mounting recesses 141 in the upper face of the first housing 140, and the pair of electric wire holding pieces 135 of the cover 130 are accommodated in the pair of electric wire holding piece recesses 152 of the first housing 140.

In the process of mounting the cover 130 to the first housing 140, the locking portion 136 of the cover 130 first slides on the bottom face 141a of the cover mounting recess 141 in the lower face of the first housing 140, and then enters the temporary locked portion 154 and engages with the temporary locked portion 154. Accordingly, the cover 130 is locked to the first housing 140 at the temporary locking position, and the cover 130 is completely mounted to the first housing 140 to obtain the voltage detection unit 105. As described later, the voltage detection unit 105 obtained after the cover 130 is completely mounted to the first housing 140 (in a state in which the cover 130 is locked at the temporary locking position) is to be used for assembling the conductive module 103 (see FIG. 1).

In a state in which the cover 130 is locked at the temporary locking position, the facing portion 131 of the cover 130 (more specifically, the pair of upper and lower extension portions 133b) does not cover the tip portion 112a of the voltage detection terminal 110. Thus, the upper and lower faces of the tip portion 112a of the voltage detection terminal 110 are also exposed by the notch 143.

Further, the pair of electric wire holding pieces 135 of the cover 130 are arranged above the opening of a part of the straight portions 147 and the bent portion 148 of the electric wire accommodating recess 146. This prevents the electric wire 120 from coming out of the electric wire accommodating recess 146. Further, the extension ends of the pair of electric wire holding pieces 135 are received in the pair of storage holes 153. Accordingly, it is possible to prevent unintended deformation such as misalignment of the pair of electric wire holding pieces 135 or separation of the pair of electric wire holding pieces 135 from the electric wire accommodating recess 146. Further, the extension portion 132 of the cover 130 is disposed above the opening of the bending vertex 148a of the bent portion 148 of the electric wire accommodating recess 146. Accordingly, it is possible to strongly prevent the electric wire 120 from being wired in a manner coming out of the electric wire accommodating recess 146 and straddling the bent portion 148 (that is, shortcutting the bent portion 148). In this way, it is possible to reduce the possibility of occurrence of a specific failure caused by the electric wire 120 coming out of the bent portion 148 of the electric wire accommodating recess 146.

When the cover 130 is further pushed leftward relative to the first housing 140 in a state in which the cover 130 is locked at the temporary locking position, the extension ends of the pair of electric wire holding pieces 135 of the cover 130 further enter and are stored in the pair of storage holes 153. Simultaneously, the locking portion 136 of the cover 130 goes beyond the temporary locked portion 154 and then enters the inside of the final locked portion 155 and is engaged with the final locked portion 155 (see FIG. 6). Thus, the cover 130 is locked to the first housing 140 at the final locking position.

In a state in which the cover 130 is locked at the final locking position, as illustrated in FIGS. 5 and 6, the entire cover mounting recesses 141 are covered with the cover 130, and thus the entire electric wire accommodating recess 146 is covered with the extension portion 132 of the cover 130. This prevents the electric wire 120 from coming out of the electric wire accommodating recess 146. Further, as illustrated in FIG. 6, the facing portion 131 of the cover 130 (more specifically, the pair of upper and lower extension portions 133b) covers the upper and lower faces of the tip portion 112a of the voltage detection terminal 110. Accordingly, the entire voltage detection terminal 110 is covered with the facing portion 131 of the cover 130, so that the voltage detection terminal 110 can be reliably protected.

As described above, the voltage detection unit 105 obtained after the cover 130 is completely mounted to the first housing 140 (in a state in which the cover 130 is locked at the temporary locking position) is used for assembling the conductive module 103 (see FIG. 1). Specifically, first, as illustrated in FIGS. 2 and 3, the flange 104a of the conductive board 104 is fitted into the recess 105a of the voltage detection unit 105, so that the voltage detection unit 105 is coupled to the right side of the conductive board 104.

In this state, as can be understood from FIG. 3, a part of the flange 104a of the conductive board 104 overlaps the lower side of the tip portion 112a of the voltage detection terminal 110, and the upper face of the tip portion 112a of the voltage detection terminal 110 is exposed upward and the lower face of a part of the flange 104a of the conductive board 104 is exposed downward due to the presence of the notch 143 of the first housing 140.

Next, the upper face of the tip portion 112a of the voltage detection terminal 110 exposed upward and the lower face of a part of the flange 104a of the conductive board 104 exposed downward are used to fix the tip portion 112a of the voltage detection terminal 110 and the part of the flange 104a of the conductive board 104 by a method such as ultrasonic joining or welding. Thereafter, the cover 130 is moved from the temporary locking position to the final locking position, and the voltage detection unit 105 is completely assembled to the conductive board 104.

Next, a procedure for assembling the temperature detection unit 106 to the conductive board 104 will be described. To assemble the temperature detection unit 106 to the conductive board 104, first, the second housing 160 is coupled to the conductive board 104. Thereafter, the thermistor 170 is assembled to the second housing 160.

To couple the second housing 160 to the conductive board 104, as illustrated in FIG. 7, the flange 104b of the conductive board 104 is fitted in the recess 106a of the second housing 160. Thus, the second housing 160 is coupled to the left side of the conductive board 104. In a state where the conductive board 104 and the second housing 160 are coupled to each other, the right end of the first recess 162 of the thermistor accommodating recess 161 communicates with a part of the recess 106a in the front-rear direction, thereby exposing the part 104b of the conductive board 104 in the recessed groove at the right end of the first recess 162 (see FIGS. 7 and 10).

Next, the thermistor 170 is assembled to the second housing 160. Therefore, the case 172 holding the thermistor element 171 is fitted into the second recess 163 from above such that the pair of holding portions 174 (more specifically, the pair of lateral walls 176) of the case 172 enter the through hole 165, the top plate 173 blocks the opening of the second recess 163 of the thermistor accommodating recess 161, the extended plate 182 blocks the opening of the communication recess 164, the electric wire 190 extending from the thermistor element 171 extends to the outside of the second housing 160 via the communication recess 164, and the four locking projections 179 of the case 172 are respectively locked to the four locking holes 166 of the second recess 163.

In a state where the thermistor 170 is completely accommodated in the second housing 160, as illustrated in FIG. 10, the thermistor element 171 is disposed at a position closer to the part 104b of the conductive board 104 exposed in the recessed groove of the first recess 162 than is the case 172. The end on the one side in the longitudinal direction of the thermistor element 171 is adjacent to the part 104b of the conductive board 104 and is exposed in the recessed groove at the boundary between the first recess 162 and the second recess 163. That is, the thermistor 170 is accommodated in the second housing 160 in a posture inclined relative to the front-rear direction so that the thermistor element 171 approaches the conductive board 104. In other words, the part 104b of the conductive board 104 and the end on the one side in the longitudinal direction of the thermistor element 171 are exposed while being adjacent to each other in the recessed groove of the thermistor accommodating recess 161.

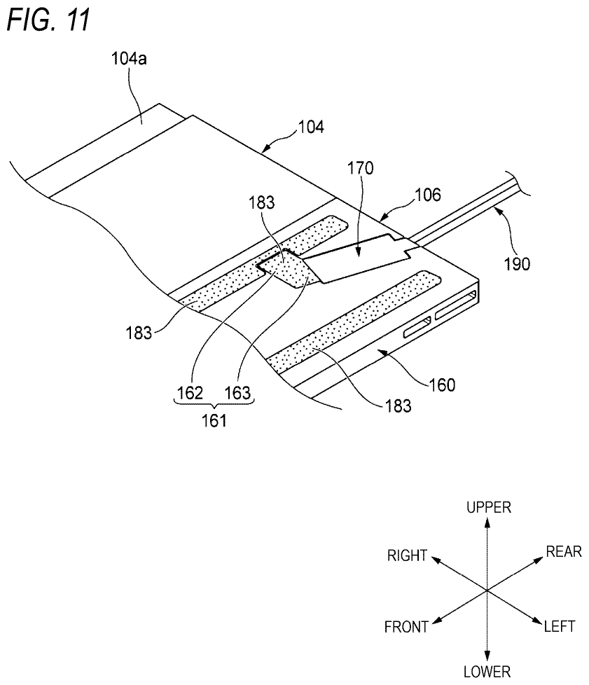

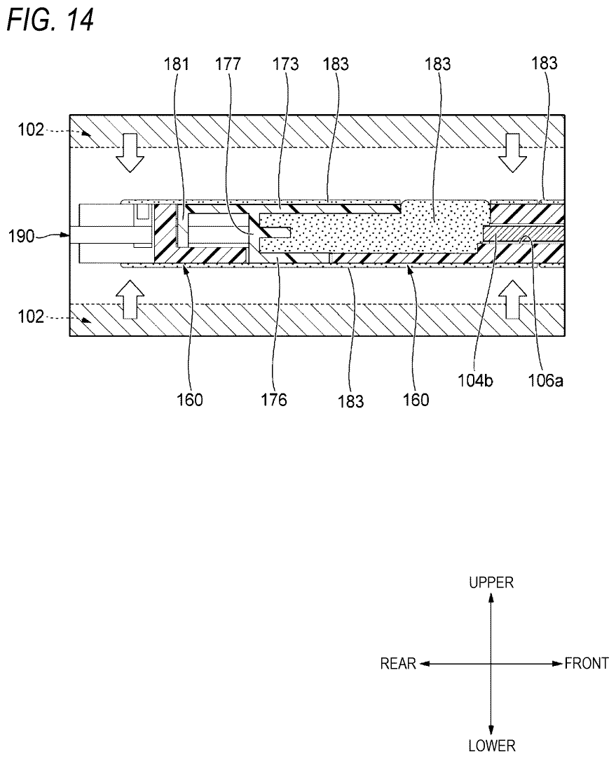

Next, as illustrated in FIGS. 11 to 14, a heat-conductive sealing material 183 having an appropriate viscosity is applied to the upper and lower faces of the second housing 160, and is filled in the recessed groove of the thermistor accommodating recess 161 (more specifically, the gap region in the recessed groove excluding the region occupied by the thermistor 170 and the part 104b of the conductive board 104). The heat conductivity of the material constituting the sealing material 183 is better than the heat conductivity of the material constituting the second housing 160. The sealing material 183 has sufficient flexibility at the time of filling, and is cured with time. In this example, the sealing material 183 is applied to both the upper and lower faces of the second housing 160 in a pair of stripes extending in the front-rear direction at an interval in the left-right direction (see FIG. 11). Here, as illustrated in FIG. 14, the movement toward the rear side (the other side in the longitudinal direction of the thermistor 170; the left side in FIG. 14) of the sealing material 183 filled in the recessed groove of the thermistor accommodating recess 161 is blocked by the pair of back walls 177 provided in the case 172. Therefore, the sealing material 183 filled in the recessed groove of the thermistor accommodating recess 161 is prevented from leaking to the outside of the second housing 160 via the communication recess 164.

As described above, by filling the sealing material 183 in the recessed groove of the thermistor accommodating recess 161, as illustrated in FIG. 13, the sealing material 183 comes into contact with both the thermistor element 171 and the part 104b of the conductive board 104 exposed in the recessed groove in the thermistor accommodating recess 161. Accordingly, an air layer that hinders the heat conduction therebetween is less likely to exist as compared to a case in which the thermistor element 171 and the part 104b of the conductive board 104 are simply disposed adjacent to each other. Accordingly, the thermistor 170 can accurately measure the temperature of the conductive board 104 (in other words, for example, the temperature of the power storage module 102 conducted through the conductive board 104 in the stacked power storage device 101). Further, the thermistor element 171 is disposed at a position closer to the part 104b of the conductive board 104 than is the case 172. Therefore, the case 172, which may impair the heat conductivity, is not to be arranged between the thermistor element 171 and the part 104b of the conductive board 104. This can further improve the accuracy of the temperature measurement by the thermistor 170. The sealing material 183 has an effect of preventing the thermistor 170 from unintentionally coming out of the thermistor accommodating recess 161. Thus, the temperature detection unit 106 is completely assembled to the conductive board 104.

Either the procedure of assembling the voltage detection unit 105 to the conductive board 104 or the procedure of assembling the temperature detection unit 106 to the conductive board 104 may be executed first. The conductive module 103 is completely assembled when both the procedure of assembling the voltage detection unit 105 to the conductive board 104 and the procedure of assembling the temperature detection unit 106 to the conductive board 104 are executed.

The conductive module 103 thus obtained is used for assembling the power storage device 101 illustrated in FIG. 1. Specifically, the power storage modules 102 and the conductive modules 103 are alternately stacked in the upper-lower direction, and the stacked body is fixed by a predetermined fitting or the like, thereby obtaining the power storage device 101.

As illustrated in FIG. 13, when the power storage modules 102 and the conductive modules 103 are alternately stacked in the upper-lower direction, the sealing material 183 applied in a stripe shape on the upper and lower faces of the second housing 160 is pressed against the power storage modules 102 adjacent to each other in the upper-lower direction, thereby pushing out the sealing material 183 continuously over substantially the entire upper and lower faces of the second housing 160. This improves the sealing performance (waterproof property) between the power storage modules 102 and the conductive modules 103 adjacent to each other in the upper-lower direction. Similarly, the sealing material 183 filled in the thermistor accommodating recess 161 is also pressed against the power storage module 102 adjacent on the upper side, so that the gap region in the thermistor accommodating recess 161 is further filled with a higher density. Accordingly, an air layer that hinders heat conduction between the thermistor element 171 and the part 104b of the conductive board 104 is less likely to exist. As a result, the thermistor 170 can more accurately measure the temperature of the conductive board 104 (in other words, for example, the temperature of the power storage module 102 conducted through the conductive board 104 in the stacked power storage device 101).

### <Operations and Effects>

As described above, according to the conductive module 103 and the power storage device 101 according to the present embodiment, the cover 130 can be locked to the first housing 140 while connecting the voltage detection terminal 110 accommodating the electric wire 120 to the tip portion 111a in the terminal accommodating recess 142 of the first housing 140 and exposing the tip portion 112a of the voltage detection terminal 110. Therefore, when the voltage detection unit 105 as the detection target is electrically connected to the conductive board 104 (for example, the conductive board 104 used in the stacked power storage device 101 or the like), for example, after the voltage detection unit 105 is assembled to the conductive board 104, the exposed tip portion 112a of the voltage detection terminal 110 can be fixed to the conductive board 104 using a method such as ultrasonic joining or welding. This does not require another component for connection as compared to typical bolt fastening or the like, and can easily align the two components and reduce the contact resistance at the contact point as compared to the connection methods of the related art described above. Further, by disposing the cover 130 at the final locking position after the connection between the conductive board 104 and the voltage detection terminal 110, the tip portion 112a of the voltage detection terminal 110 (that is, the contact point therebetween) can be covered and protected by the cover 130.

Further, by accommodating the thermistor 170 in the thermistor accommodating recess 161 of the second housing 160, the thermistor element 171 and the part 104b of the conductive board 104 are arranged in the recessed groove of the thermistor accommodating recess 161, and the heat-conductive sealing material 183 is disposed in the recessed groove in contact with both the thermistor element 171 and the part 104b of the conductive board 104. Accordingly, an air layer that hinders heat conducted between the thermistor element 171 and the conductive board 104 is less likely to exist as compared to a case where the thermistor element 171 and the conductive board 104 are simply disposed adjacent to each other. Accordingly, the thermistor 170 can accurately measure the temperature of the conductive board 104 (in other words, for example, the temperature of the power storage module 102 conducted through the conductive board 104 in the stacked power storage device 101).

Therefore, the conductive module 103 and the power storage device 101 according to the present embodiment are excellent in workability for conductively connecting to the conductive board 104 as the detection target. Furthermore, the conductive module 103 and the power storage device 101 according to the present embodiment can improve the accuracy of the temperature measurement by the thermistor 170.

Further, the thermistor 170 is accommodated in the thermistor accommodating recess 161 of the second housing 160 in a posture in which the thermistor element 171 is closer to the conductive board 104 than is the case 172. Therefore, the case 172, which may impair the heat conductivity, is not arranged between the thermistor element 171 and the conductive board 104. This can further improve the accuracy of the temperature measurement by the thermistor 170.

### Other Embodiments

The present disclosure is not limited to the embodiments described above, and various modifications can be adopted within the scope of the present disclosure. For example, the present disclosure is not limited to the embodiments described above, and modifications, improvements, and the like can be made appropriately. In addition, materials, shapes, sizes, numbers, arrangement positions, and the like of components in the embodiments described above are freely selected and are not limited as long as the present disclosure can be implemented.

Here, the features of the embodiments of the conductive module 103 and the power storage device 101 according to the present disclosure described above are briefly summarized and listed in the following [1] to [3], respectively.

[1] A conductive module (103) including:
a conductive board (104);
a voltage detection terminal (110) having a first location (112a) configured to be conductively connected to the conductive board (104);
a temperature measurer (170) including a temperature-measuring element (171) and a case (172) holding the temperature-measuring element (171);
a plate-shaped housing (140, 160) assembled to the conductive board (104), the housing having a terminal accommodating recess (142) accommodating the voltage detection terminal (110) and a temperature measurer accommodating recess (161) accommodating the temperature measurer (170);
a heat-conductive filler (183) disposed in a recessed groove of the temperature measurer accommodating recess (161);
a cover (130) configured to be locked to the housing (140) at a temporary locking position where the first location (112a) of the voltage detection terminal (110) accommodated in the terminal accommodating recess (142) is not covered and a final locking position where the first location (112a) is covered; and
an electric wire (120) conductively connected to a second location (111a) of the voltage detection terminal (110) and drawn out to the outside of the housing (140), in which
the housing (160) is configured such that a part of the conductive board (104) is exposed in the recessed groove of the temperature measurer accommodating recess (161), and
the filler (183) is in contact with both the temperature-measuring element (171) and the part of the conductive board (104).

According to the conductive module having the configuration of the above [1], the cover can be locked to the housing while accommodating the voltage detection terminal whose second location is connected to the electric wire in the terminal accommodating recess of the housing and exposing the first location of the voltage detection terminal. Therefore, when the voltage detection unit is electrically connected to a conductive board as the detection target (for example, a conductive board or the like used in a stacked power storage device), for example, after the voltage detection unit is assembled to the conductive board, the exposed first location of the voltage detection terminal can be fixed to the conductive board using a method such as ultrasonic joining or welding. This does not require another component for connection as compared to typical bolt fastening or the like, and can easily align the two components and reduce the contact resistance at the contact point as compared to the connection methods of the related art described above. Further, by disposing the cover at the final locking position after the conductive board and the voltage detection terminal are connected, the first location of the voltage detection terminal (that is, the contact point therebetween) can be covered and protected by the cover.

Further, the temperature measurer is accommodated in the temperature measurer accommodating recess of the housing, so that both the temperature-measuring element of the temperature measurer and a part of the conductive board exposed in the recessed groove of the temperature measurer accommodating recess are arranged in the recessed groove. Simultaneously, a heat-conductive filler (for example, a sealing material that is flexible at the time of filling and is hardened with time) is disposed in the recessed groove to be in contact with both the temperature-measuring element and a part of the conductive board. Accordingly, an air layer that hinders the heat conduction therebetween is less likely to exist as compared to a case in which the temperature-measuring element and the conductive board are simply disposed adjacent to each other. Accordingly, the temperature measurer can accurately measure the temperature of the conductive board (in other words, for example, the temperature of the power storage module conducted through the conductive board in a stacked power storage device).

Accordingly, the conductive module of the present configuration is excellent in workability for conductively connecting to the detection target. Further, the conductive module of the present configuration can improve the accuracy of the temperature measurement by the temperature measurer.

[2] The conductive module (103) according to the above [1], in which the temperature measurer (170) is accommodated in the temperature measurer accommodating recess (161) of the housing (160) in a posture in which the temperature-measuring element (171) is closer to the conductive board (104) than is the case (172).

According to the conductive module having the configuration of the above [2], the case, which impairs the heat conductivity, is not to be arranged between the temperature-measuring element and the conductive board. This can further improve the accuracy of the temperature measurement by the temperature measurer.

[3] A power storage device (101) including:
the conductive module (103) according to the above [1] or [2]; and
a power storage module (102) configured to be charged and discharged, on which the conductive module (103) is stacked.

According to the power storage device having the configuration of the above [3], the cover can be locked to the housing while accommodating the voltage detection terminal whose second location is connected to the electric wire in the terminal accommodating recess of the housing and exposing the first location of the voltage detection terminal. Therefore, when the voltage detection unit is electrically connected to a conductive board as the detection target (for example, a conductive board or the like used in a stacked power storage device), for example, after the voltage detection unit is assembled to the conductive board, the exposed first location of the voltage detection terminal can be fixed to the conductive board using a method such as ultrasonic joining or welding. This does not require another component for connection as compared to typical bolt fastening or the like, and can easily align the two components and reduce the contact resistance at the contact point as compared to the connection methods of the related art described above. Further, by disposing the cover at the final locking position after the conductive board and the voltage detection terminal are connected, the first location of the voltage detection terminal (that is, the contact point therebetween) can be covered and protected by the cover.

Further, the temperature measurer is accommodated in the temperature measurer accommodating recess of the housing, so that both the temperature-measuring element of the temperature measurer and a part of the conductive board exposed in the recessed groove of the temperature measurer accommodating recess are arranged in the recessed groove. Simultaneously, a heat-conductive filler (for example, a sealing material that is flexible at the time of filling and is hardened with time) is disposed in the recessed groove to be in contact with both the temperature-measuring element and a part of the conductive board. Accordingly, an air layer that hinders the heat conduction therebetween is less likely to exist as compared to a case in which the temperature-measuring element and the conductive board are simply disposed adjacent to each other. Accordingly, the temperature measurer can accurately measure the temperature of the conductive board (in other words, for example, the temperature of the power storage module conducted through the conductive board in a stacked power storage device).

Accordingly, the power storage device of the present configuration is excellent in workability for conductively connecting to the detection target. Further, the power storage device of the present configuration can improve the accuracy of the temperature measurement by the temperature measurer.

1. A conductive module comprising:
a conductive board;
a voltage detection terminal having a first location configured to be conductively connected to the conductive board;
a temperature measurer including a temperature-measuring element and a case holding the temperature-measuring element;
a plate-shaped housing assembled to the conductive board, the housing having a terminal accommodating recess accommodating the voltage detection terminal and a temperature measurer accommodating recess accommodating the temperature measurer;
a heat-conductive filler disposed in a recessed groove of the temperature measurer accommodating recess;
a cover configured to be locked to the housing at a temporary locking position where the first location of the voltage detection terminal accommodated in the terminal accommodating recess is not covered and a final locking position where the first location is covered; and
an electric wire conductively connected to a second location of the voltage detection terminal and drawn out to the outside of the housing, wherein:
the housing is configured such that a part of the conductive board is exposed in the recessed groove of the temperature measurer accommodating recess; and
the filler is in contact with both the temperature-measuring element and the part of the conductive board.

2. The conductive module according to claim 1, wherein
the temperature measurer is accommodated in the temperature measurer accommodating recess of the housing in a posture in which the temperature-measuring element is closer to the conductive board than is the case.

3. A power storage device comprising:
the conductive module according to claim 1; and
a power storage module configured to be charged and discharged, on which the conductive module is stacked.
